(19) United States
(12) Patent Application Publication
(10) Pub. No.: US 2026/0258164 A1
(43) Pub. Date: Sep. 3, 2026

(54) USE OF SPECIFIC PHOTOINITIATORS IN A PHOTOPOLYMERIZATION PROCESS USING COMBINED LED LIGHT WAVELENGTHS

(71) Applicant: IGM RESINS ITALIA S.R.L., Milano (IT)

(72) Inventor: Emilio Cremona, Venegono Superiore (VA) (IT)

(73) Assignee: IGM RESINS ITALIA S.R.L., Milano (IT)

(21) Appl. No.: 19/159,619

(22) PCT Filed: Mar. 12, 2024
(86) PCT No.: PCT/IB2024/052366

§ 371 Date: Aug. 26, 2025

(30) Foreign Application Priority Data
Mar. 14, 2023 (IT) 102023000004737

(51) Int. Cl. C08F 2/50; G03F 7/00; G03F 7/031

(52) U.S. Cl. CPC C08F 2/50; G03F 7/0037; G03F 7/031

(57) ABSTRACT

The present invention relates to the use of certain photoinitiators and compositions thereof in a photopolymerization process which makes use of combined LED light wavelengths. The invention also relates to a photopolymerizing process which makes use of said specific photoinitiators with different LED light wavelengths, as well as articles of manufacture, including printed, coated and fabricated assemblies obtained by said process.

### PRIOR ART

In the last decade, the design and the development of new photoinitiators (PIs) has been driven from the growing use of LED lamps.

Typically, LED lamps have only a single emission band in the range 365-420 nm, requesting photoinitiators able to work at these wavelengths. Various attempts were made to develop new photoinitiators able to cure under these lamps, some examples are glyoxylate 3-ketocoumarins (WO2021070152), benzoyl phenyltelluride PIs (Macromolecules, 2014, 47(16), 5526-5531), silicon based PIs (JP2010229169, Macromolecules, 2009, 42(16), 6031-6037, Macromolecules 2007, 40(24), 8527-8530, Macromol. Rapid Commun. 2017, 38, 1600470, Macromolecules, 2017, 50(17), 6911-6923), fluorine based PIs (US2019/0155153).

Unfortunately, these photoinitiators show some limitations, such as low surface curing and post-cure yellowing, which makes said PIs inappropriate in polymerizable systems involving transparent varnishes.

In the last year, new LED lamps emitting between 270-290 nm have been developed, but the photoinitiators able to work at such wavelengths are still missing.

So, there exists the need of new technical solutions able to improve the surface curing of PIs without affecting the good reactivity of these products and/or to limit post-cure yellowing.

### AIMS OF THE INVENTION

It is a first aim of the invention to provide for the use of specific PIs as photoinitiators in a process which provides improved photocurable effects with respect to the prior art.

It is a further aim of the invention to provide for a process which makes use of said specific PIs as photoinitiators.

It is a further aim of the invention to provide for articles of manufacture, including printed, coated and fabricated assemblies obtained by the above process.

### DESCRIPTION OF THE INVENTION

Now, surprising, we observed that a specific class of photoinitiators is able to achieve good surface curing and low post curing yellowing when combined LED wavelengths are used.

According to one of its aspects, the present invention relates to the use of at least a compound of formula (I)

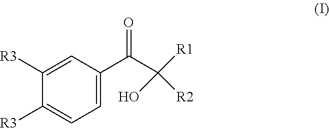

wherein:
R1 and R2, each independently, in any occurrence, are C1-C4 alkyl;
   and
   either
R3 is H;
R4 is selected from C1-C6-alkoxy, hydroxy-C1-C4-alkoxy, linear or branched C1-C12-alkyl, unsubstituted phenoxy, unsubstituted benzyl, unsubstituted phenyl, and a group of formula (a) or (b):

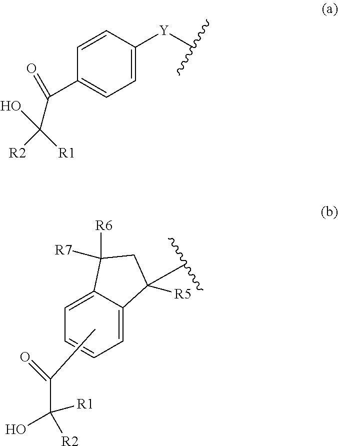

wherein
Y is selected from —O—, —CH2-, —CHOH—, —CH(Alk)- and —C(Alk)₂-, wherein Alk is a C1-C4 alkyl;
R5, R6 and R7, each independently, are C1-C4-alkyl; and
the wavy line indicates the link to the phenyl group of formula (I);
   or
R3 and R4, together with the two carbon atoms to which they are linked, form a group of formula (c)

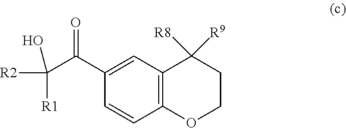

wherein
R8 and R9, each independently, are H or C1-C4-alkyl; and
the stars indicate the positions of R3 and R4 in formula (I);
   as photoinitiators in a photopolymerizing process of a photopolymerizable composition, characterized in that said photopolymerizing process is carried out by means of at least two different LED light wavelengths, at least one being equal or lower than 300 nm and at least one being higher than 300 nm, provided that the at least two LED light wavelengths are separated by at least 10 nm, preferably at least 20 nm, more preferably at least 30 nm,
   wherein said photopolymerizable composition does not comprise any liquid crystal.

Group of formula (b) is a mixture of the following groups (b′) and (b″):

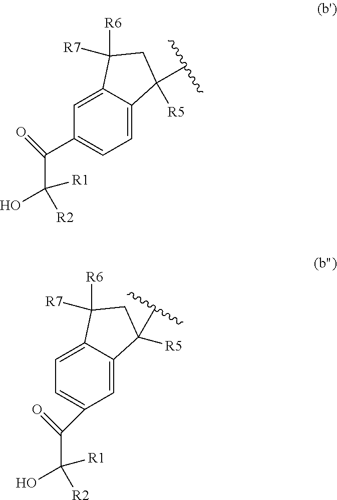

Preferably, R1 and R2 are, each independently, a methyl or ethyl group, more preferably R1 and R2 are both a methyl group.

Preferably, R4 is hydroxy-C1-C4-alkoxy group, more preferably a hydroxy-ethoxy group.

Preferably, Y is selected from —O— and —CH2-.

Preferably, Alk is a methyl or ethyl group, more preferably is a methyl group.

Preferably, R5, R6 and R7 are, each independently, a methyl or ethyl group, more preferably they are all a methyl group.

Preferably, R8 and R9 are, each independently, a methyl or ethyl group, more preferably R8 and R9 are both a methyl group.

Preferably, group (c) is fused with the compound of formula (I) so that the oxygen atom of group (c) is in para position with respect to the keto group in formula (I).

According to a preferred embodiment, the compounds of formula (I) are the following:

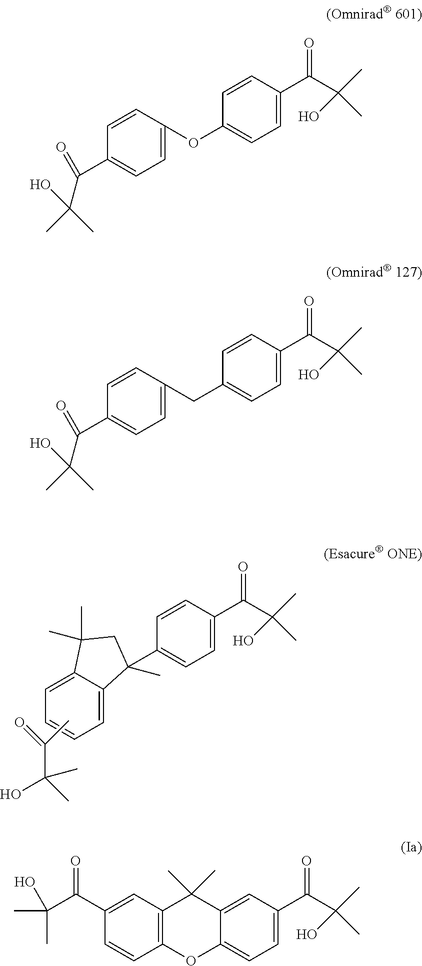

The above compounds are known and/or commercially available, or they can be prepared according to known methods.

Compounds of formula (I) are not liquid crystals.

According to another of its aspects, the present invention relates to the use of a photopolymerizable composition comprising:
a) from 50 to 99.9%, preferably from 70 to 98.9% by weight, based on the total content of the composition, of at least one ethylenically unsaturated compound;
b) from 0.1 to 20%, preferably from 0.5 to 15%, and more preferably from 1 to 12% by weight, based on the total content of the composition, of at least one compound of formula (I) as above defined; and
   in a photopolymerizing process, characterized in that said photopolymerizing process is carried out by means of at least two different LED light wavelengths, at least one being from 260 nm to 290 nm and at least one being from 365 nm to 405 nm
   wherein said photopolymerizable composition does not comprise any liquid crystal.

Preferably, said at least one compound (b) is present in an amount from 1 to 12%, for instance 1, 2, 3, 4, 5, 6, 7, 8, 9, 10, 11 or 12%.

According to the present invention, the terms “photocuring” and “photopolymerizing” and related terms, are synonyms.

The expression “based on the total content of the composition” means that the % weight amounts of any of the components is calculated with respect to the sum of the weight of all the components of the composition, including any possible further additional components (in addition to a) and b) above), but possible water and/or solvents which may be present in the composition are not considered for the calculation of said % weight amounts.

According to another of its aspects, the present invention relates to a process for photocuring photopolymerizable compositions coatings, adhesives and inks, which process comprises:
i. providing a photopolymerizable composition as above defined;
ii. coating or printing said photopolymerizable composition onto a substrate, and
iii. photocuring said coated or printed composition with at least two different LED light wavelengths, at least one being equal or lower than 300 nm and at least one being higher than 300 nm, provided that the at least two LED light wavelengths are separated by at least 10 nm, preferably at least 20 nm, more preferably at least 30 nm,
   wherein said photopolymerizable composition does not comprise any liquid crystal.

According to another of its aspects, the present invention relates to a process for three-dimensional printing which comprising photocuring with a light source a mixture comprising the composition as above defined, wherein said photopolymerizable composition does not comprise any liquid crystal.

According to another of its aspects, the present invention relates to an article of manufacture, including printed, coated and fabricated assemblies obtained by the process of the invention.

The photocurable compositions of the present invention can also comprise one or more of the following components: (c) accelerators and/or coinitiators, (d) sensitizers and/or (e) further photoinitiators and/or (f) conventional additives, in addition to compounds (a) and (b).

According to a preferred embodiment, the photopolymerizable composition used the processes of the invention comprises at least components (a) and (b) preferably at least (a), (b) and (e), and more preferably (a), (b), (c), (d) and (e) as above defined.

The photoinitiators as above defined can be used in photocurable compositions comprising ethylenically unsaturated compounds (a). Said unsaturated compounds (a) can contain one or more olefinic double bonds. They can be low-molecular weight (monomeric) or high-molecular weight (oligomeric) compounds.

Examples of suitable low molecular weight monomers (monomeric compounds) having one double bond are alkyl or hydroxyalkyl acrylates or methacrylates, such as methyl-, ethyl-, butyl-, 2-ethylhexyl-, 2-hydroxyethyl- or isobornyl-acrylate; and methyl or ethyl methacrylate. Further examples are resins modified with silicon or fluorine, e.g. silicone acrylates. Further examples of these monomers are acrylonitrile, acrylamide, methacrylamide, N-substituted (meth)acrylamides, styrene, alkylstyrenes and halogeno styrenes, vinyl esters such as vinyl acetate, vinyl ethers such as iso-butyl vinyl ether, N-vinylpyrrolidone, vinyl chloride or vinylidene chloride.

Examples of monomers having more than one double bond are the ethylene glycol diacrylate, propylene glycol diacrylate, neopentyl glycol diacrylate, hexamethylene glycol diacrylate, bisphenol A diacrylate, 4,4′-bis-(2-acryloyloxyethoxy)-diphenylpropane, trimethylolpropane triacrylate, pentaerythritol triacrylate or tetraacrylate, vinyl acrylate, divinyl benzene, divinyl succinate, diallyl phthalate, triallyl phosphate, triallyl isocyanurate or tris-(2-acryloylethyl) isocyanurate.

Examples of high-molecular weight (oligomeric) polyunsaturated compounds are acrylated epoxy resins, acrylated or vinyl-ether- or epoxy-group-containing polyesters, acrylated polyurethanes or acrylated polyethers. Further examples of unsaturated oligomers are unsaturated polyester resins which are usually prepared from maleic acid, phthalic acid and one or more diols and which have molecular weights of from about 500 Da to 3,000 Da. Such unsaturated oligomers can also be referred to as prepolymers.

Examples of compounds (a) which are particularly suitable for the implementation of the present invention, are esters of ethylenically unsaturated carboxylic acids and polyols or polyepoxides, and polymers containing ethylenically unsaturated groups in the chain or in side groups, e.g. unsaturated polyesters, polyamides and polyurethanes and copolymers thereof, alkyl resins, polybutadiene and butadiene copolymers, polyisoprene and isoprene copolymers, polymers and copolymers having (meth)acrylic groups in side chains, as well as mixtures thereof.

Illustrative examples of unsaturated carboxylic acids or anhydrides, useful for the preparation of the above esters, are acrylic acid, methacrylic acid, maleic anhydride, crotonic acid, itaconic acid, cinnamic acid and unsaturated fatty acids such as linolenic acid and oleic acid. Acrylic and methacrylic acid are preferred. Examples of polyols, which can also be esterified, are aromatic and aliphatic and cycloaliphatic polyols, preferably aliphatic and cycloaliphatic polyols.

Aromatic polyols are, for example, hydroquinone, 4,4′-dihydroxydiphenyl, 2,2-di(4-hydroxyphenyl) propane, as well as novolaks and resoles. Polyepoxides, which can be esterified, include those based on the said polyols, especially the reaction products between aromatic polyols and epichlorohydrin. Also suitable as polyols are polymers and copolymers that contain hydroxyl groups in the polymer chain or in side groups, for example polyvinyl alcohol and copolymers thereof or polymethacrylic acid hydroxyalkyl esters or copolymers thereof. Further suitable polyols are oligoesters carrying hydroxyl terminal groups.

Examples of aliphatic and cycloaliphatic polyols include alkylenediols containing preferably from 2 to 12 carbon atoms, such as ethylene glycol, 1,2- or 1,3-propanediol, 1,2-, 1,3- or 1,4-butanediol, pentanediol, hexanediol, octanediol, dodecanediol, diethylene glycol, triethylene glycol, polyethylene glycols having molecular weights of preferably from 200 Da to 1,500 Da, 1,3-cyclopentanediol, 1,2-, 1,3- or 1,4-cyclohexanediol, 1,4-dihydroxymethyl cyclohexane, glycerol, tris(p-hydroxy-ethyl)amine, trimethylolethane, trimethylolpropane, pentaerythritol, dipentaerythritol and sorbitol.

Further suitable ethylenically unsaturated compounds (a) are unsaturated polyamides obtained from unsaturated carboxylic acids and aromatic, aliphatic and cycloaliphatic polyamines having preferably from 2 to 6, preferably from 2 to 4, amino groups. Examples of such polyamines are: ethylenediamine, 1,2- or 1,3-propylenediamine, 1,2-, 1,3- or 1,4-butylenediamine, 1,5-pentylenediamine, 1,6-hexylenediamine, octylenediamine, dodecylene diamine, 1,4-diaminocyclohexane, isophoronediamine, phenylene diamine, bisphenylenediamine, di-(β-aminoethyl) ether, diethylene triamine, triethylenetetramine and di(β-aminoethoxy)- and di(β-aminopropoxy)ethane. Other suitable polyamines are polymers and copolymers which may contain additional amino groups in the side chain and oligoamides containing amino end groups.

Specific examples of such unsaturated polyamides are methylenebisacrylamide, 1,6-hexamethylene bisacrylamide, diethylenetriamine trismethacrylamide, bis(methacrylamidopropoxy) ethane and N-[(p-hydroxyethoxy)ethyl]-acrylamide.

Unsaturated polyurethanes are also suitable for the implementation of the present invention as components (a), for example those derived from saturated or unsaturated diisocyanates and unsaturated or saturated diols. Polybutadiene and polyisoprene and copolymers thereof may also be used.

Suitable monomers include, for example, olefins, such as ethylene, propene, butene and hexene, (meth)acrylates, acrylonitrile, styrene and vinyl chloride.

Polymers having unsaturated (meth)acrylate groups in the side chain can also be used as component (a). They may typically be reaction products of epoxy resins based on novolac with (meth)acrylic acid; homo- or copolymers of vinyl alcohol or hydroxyalkyl derivatives thereof that have been esterified with (meth)acrylic acid; and homo- and co-polymers of (meth)acrylates that have been esterified with hydroxyalkyl (meth)acrylates.

The photocurable composition may further comprise a one or more coinitiators (c), also referred to as accelerators in an amount from 0 to 20% by weight, preferably from 0 to 15%, and more preferably from 0.2% to 15% by weight.

Suitable examples of accelerators/coinitiators (c) are alcohols, thiols, thioethers, amines or ethers that have an available hydrogen, bonded to a carbon adjacent to the heteroatom, disulfides and phosphines, e.g. as described in EP 438 123 and GB 2 180 358.

Suitable examples of amine accelerators/co-initiators include, but are not limited to, aliphatic, cycloaliphatic, aromatic, aryl-aliphatic, heterocyclic, oligomeric or polymeric amines. They can be primary, secondary or tertiary amines, for example butyl amine, dibutyl amine, tributyl amine, cyclohexyl amine, benzyldimethyl amine, di-cyclohexyl amine, N-phenyl glycine, triethyl amine, phenyl-diethanol amine, triethanolamine, piperidine, piperazine, morpholine, pyridine, quinoline, esters of dimethylamino benzoic acid, Michler's ketone (4,4′-bis-dimethyl aminobenzophenone) and derivatives thereof.

As the amine accelerators/co-initiators, an amine-modified acrylate compound can be used; examples of such amine-modified acrylate include acrylates modified by reaction with a primary or secondary amine that are described in U.S. Pat. No. 3,844,916, EP 280222, U.S. Pat. No. 5,482,649 or U.S. Pat. No. 5,734,002.

Multifunctional amine and polymeric amine derivatives are also suitable as co-initiators some examples are Omnipol® ASA from IGM Resins B.V., Genopol® AB-2 from Rahn A. G., Speedcure® 7040 from Lambson Limited or those described in US2013/0012611.

The photocurable compositions of the present invention can also be formulated in compositions further comprising water and/or solvents, such as organic solvents.

Photosensitizers (d) can be present in an amount comprised between 0.01 and 15% by weight, based on the total content of the composition, preferably between 0.01 and 10% by weight.

Examples of sensitizers are those commonly used in the art, aromatic carbonyl compounds, e.g. benzophenones, thioxanthones, anthraquinones, coumarins and 3-acylcoumarin derivatives, terphenyls, styryl ketones, and 3-(aroylmethylene)-thiazolines, camphorquinones and also eosin, rhodamine and erythrosine dyes.

Examples of thioxanthones are thioxanthone, 2-isopropyl thioxanthone, 2-chloro thioxanthone, 2-dodecyl thioxanthone, 2,4-diethyl thioxanthone, 2,4-dimethyl thioxanthone, 1-methoxycarbonyl thioxanthone, 2-ethoxycarbonyl thioxanthone, 3-(2-methoxyethoxycarbonyl) thioxanthone, 4-butoxycarbonyl thioxanthone, 3-butoxycarbonyl-7-methyl thioxanthone, 1-cyano-3-chloro thioxanthone, 1-ethoxycarbonyl-3-chloro thioxanthone, 1-ethoxycarbonyl-3-ethoxy thioxanthone, 1-ethoxycarbonyl-3-amino thioxanthone, 1-ethoxycarbonyl-3-phenylsulfuryl thioxanthone, 3,4-di[2-(2-methoxyethoxy)ethoxycarbonyl]thioxanthone, 1-ethoxycarbonyl-3-(1-methyl-1-morpholinoethyl) thioxanthone, 2-methyl-6-dimethoxymethyl thioxanthone, 2-methyl-6-(1,1-dimethoxybenzyl) thioxanthone, 2-morpholinomethyl thioxanthone, 2-methyl-6-morpholinomethyl thioxanthone, N-allylthioxanthone-3,4-dicarboximide, N-octylthioxanthone-3,4-dicarboximide, N-(1,1,3,3-tetramethylbutyl)-thioxanthone-3,4-dicarboximide, 1-phenoxy thioxanthone, 6-ethoxycarbonyl-1-2-methoxythioxanthone, 6-ethoxycarbonyl-2-methylthioxanthone, thioxanthone-2-polyethylene glycol ester, 2-hydroxy-3-(3,4-dimethyl-9-oxo-9H-thioxanthon-2-yloxy)-N,N,N-trimethyl-1-propanaminium chloride, or those described in the patent application PCT/EP2011/069514, such as n-dodecyl-7-methyl-thioxanthone-3-carboxylate and N,N-disobutyl-7-methyl-thioxanthone-3-carbamide. Also suitable are polymeric thioxanthone derivatives (e.g. Omnipol® TX from IGM Resins B.V., Genopol® TX-1 from Rahn A. G., Speedcure® 7010 from Lambson Limited).

Example of benzophenones are benzophenone, 4-phenyl benzophenone, 4-methoxy benzophenone, 4,4′-dimethoxybenzophenone, 4,4′-dimethyl benzophenone, 4,4′-dichloro benzophenone, 4,4′-dimethylamino benzophenone, 4,4′-diethylamino benzophenone, 4-methyl benzophenone, 2,4,6-trimethyl benzophenone, 4-(4-methylthiophenyl) benzophenone, 3,3′-dimethyl-4-methoxy benzophenone, methyl 2-benzoyl benzoate, 4-(2-hydroxyethylthio) benzophenone, 4-(4-tolylthio) benzophenone, 4-benzoyl-N,N,N-trimethylbenzene methanaminium chloride, 2-hydroxy-3-(4-benzoylphenoxy)-N,N,N-trimethyl-1-propanaminium chloride monohydrate, 4-(13-acryloyl-1,4,7,10,13-pentaoxatridecyl) benzophenone, 4-benzoyl-N,N-dimethyl-N-[2-(1-oxo-2-propenyl)oxylethyl-benzene methanaminium chloride, or those described in U.S. Pat. No. 9,938,231 (e.g. Omnirad® 991 from IGM Resins B.V.).

Also suitable are polymeric benzophenone derivatives (e.g. Omnipol® BP, Omnipol® 2702 and Omnipol® 682 all from IGM Resins B.V., Genopol® BP-2 from Rahn A. G. and Speedcure® 7005 from Lambson Limited).

Examples of 3-acylcoumarin derivatives are 3-benzoyl coumarin, 3-benzoyl-7-methoxy coumarin, 3-benzoyl-5,7-di(propoxy) coumarin, 3-benzoyl-6,8-dichloro coumarin, 3-benzoyl-6-chloro coumarin, 3,3′-carbonyl-bis[5,7-di(propoxy) coumarin], 3,3′-carbonyl-bis(7-methoxy coumarin), 3,3′-carbonyl-bis(7-diethylamino coumarin), 3-isobutyroyl coumarin, 3-benzoyl-5,7-dimethoxy coumarin, 3-benzoyl-5,7-diethoxy coumarin, 3-benzoyl-5,7-dibutoxy coumarin, 3-benzoyl-5,7-di(methoxyethoxy) coumarin, 3-benzoyl-5,7-di(allyloxy) coumarin, 3-benzoyl-7-dimethylamino coumarin, 3-benzoyl-7-diethylamino coumarin, 3-isobutyroyl-1,7-dimethylamino coumarin, 5,7-dimethoxy-3-(1-benzoyl) coumarin, 5,7-dimethoxy-3(1-benzoyl)-coumarin, 3-benzoylbenzo [f]coumarin, 7-diethylamino-3-thienoyl coumarin, 3-(4-cyanobenzoyl)-5,7-dimethoxy coumarin, or those described in EP2909243 and WO2017216699.

Examples of 3-(aroylmethylene) thiazolines are 3-methy-1,2-benzoylmethylene-β-benzo thiazoline, 3-methyl-2-benzoylmethylene-benzo thiazoline, 3-ethyl-2-propionylmethylene-β-benzo thiazoline.

Examples of other aromatic carbonyl compounds are acetophenone, 3-methoxyacetophenone, 4-phenylacetophenone, benzyl, such as the one described in WO 2013/164394, 2-acetylnaphthalene, 2-naphthaldehyde, 9,10-anthraquinone, 9-fluorenone, dibenzosuberone, xanthone, 2,5-bis(4-diethylaminobenzylidene) cyclopentanone, α-(para-dimethylamino benzylidene), ketones, such as 2-(4-dimethylamino-benzylidene)-indan-1-one or 3-(4-dimethylaminophenyl)-1-indan-5-yl-propenone, 3-phenylthiophthalimide, N-methyl-3,5-di(ethylthio)phthalimide.

Particularly preferred are thioxanthones, coumarins and 3-acylcoumarins.

It was observed that the above components (d) increase the activity of photoinitiators (b) without shortening the shelf life of the compositions. Moreover, such compositions have the special advantage that an appropriate choice of the sensitizer (d) allows the spectral sensitivity of photoinitiator (b) to be shifted to any desired wavelength region. The skilled in the art is able to select the suitable sensitizer (d) to make the photoinitiator(s) (b) work at any desired wavelength region.

The further possible photoinitiators (e) can be present in an amount comprised between 0.5 and 15% by weight, of the total content of the composition, preferably between 1 and 10% by weight of the composition.

Examples of other suitable photoinitiators (e) are camphorquinone, benzophenone, benzophenone derivatives, acetophenone, acetophenone derivatives, dialkoxyacetophenones, α-hydroxyketones, α-aminoketones, 4-aroyl-1,3-dioxolanes, benzoin alkyl ethers and benzyl ketals, e.g. benzyl dimethyl ketal, ketosulfones, e.g 1-[4-[(4-benzoyl-phenyl)-thio]-phenyl]-2-methyl-2-[(4-methyl-phenyl)-sulfonyl]-propan-1-one (Esacure® 1001, from IGM Resins B.V.), 3-ketocoumarins, for example as described in EP2909243 and WO2017216699, phenylglyoxylates and derivatives thereof, dimeric phenyl glyoxylates, peresters, e.g. benzophenonetetracarboxylic acid peresters, for example as described in EP 126 541, acylphosphine photoinitiators (which can be selected from mono-acylphosphine oxides, bis-acylphosphine oxides, tris-acylphosphine oxides and multifunctional mono- or bisacylphosphine oxides), halomethyltriazines, hexaaryl bisimidazole/coinitiator systems, e.g. ortho-chlorohexaphenylbisimidazole in combination with 2-mercaptobenzothiazole, ferrocenium compounds or titanocenes, for example dicyclopentadienyl-bis(2,6-difluoro-3-pyrrolo-phenyl)titanium, O-acyloxime ester photoinitiators.

Examples of α-hydroxyketones and α-aminoketones are 1-hydroxy cyclohexylphenyl ketone, 2-hydroxy-2-methyl-1-phenyl-propane-1-one, 1-[4-(2-hydroxyethoxy)phenyl]-2-hydroxy-2-methyl-1-propane-1-one, 2-hydroxy-1-{4-[4-(2-hydroxy-2-methyl-propionyl)-benzyl]phenyl}-2-methyl-propane-1-one), 2-hydroxy-1-{4-[4-(2-hydroxy-2-methyl-propionyl)-phenoxy]-phenyl}-2-methyl-propan-1-one, 2-methyl-1-(4-methylthiophenyl)-2-morpholinopropane-1-one), 2-benzyl-2-dimethylamino-1-(4-morpholinophenyl)-butane-1-one, and (2-(dimethylamino)-2-[(4-methylphenyl)methyl]-1-[4-(4-morpholinyl) phenyl]-1-butanone).

Examples of O-acyloxime ester photoinitiators are 1,2-octanedione,1-[4-(phenylthio)phenyl]-2-(O-benzoyloxime), ethanone 1-[9-ethyl-6-(2-methylbenzoyl)-9H-carbazole-3-yl]1-(O-acetyloxime) or those described in GB 2339571.

Examples of acylphosphine photoinitiators include, but are not limited to, bis(2,4,6-trimethylbenzoyl)phenylphosphine oxide, bis(2,6-dimethoxybenzoyl)-2,4,4-trimethylpentyl phosphine oxide, bis(2,4,6-trimethylbenzoyl)-(2,4-dipentyloxyphenyl), 2,4,6-trimethylbenzoyl-diphenyl phosphine oxide and ethyl (2,4,6-trimethylbenzoyl) phenylphosphinate, Phenyl(2,4,6-trimethylbenzoyl)phosphinic acid, glycerol ethoxylated trimester (Omnipol® TP from IGM Resins B.V.).

Examples of the halomethyltriazines based photoinitiators are 2-[2-(4-methoxy-phenyl)-vinyl]-4,6-bis-trichloromethyl [1,3,5]triazine, 2-(4-methoxy-phenyl)-4,6-bis-trichloromethyl [1,3,5]triazine, 2-(3,4-dimethoxyphenyl)-4,6-bis-trichloromethyl [1,3,5]triazine, 2-methyl-4,6-bis-trichloromethyl [1,3,5]triazine.

Cationic photoinitiators can be also used as the further photoinitiators (e), when the photocurable compositions according to the invention are used in hybrid systems (which in this connection mean mixtures of free-radically and cationically curing systems). Examples of suitable cationic photoinitiators are aromatic sulfonium, phosphonium or iodonium salts, as described e.g. in U.S. Pat. No. 4,950,581, or cyclopentadienylarene-iron(II) complex salts, e.g. (η⁶-isopropylbenzene)(η⁵-cyclopentadienyl) iron(II) hexafluorophosphate or photolatent acids based on oximes, as described, for example, in GB 2 348 644, U.S. Pat. Nos. 4,450,598, 4,136,055, WO 00/10972 and WO 00/26219.

The photocuring composition according to the invention may also comprise conventional additives, from 0 to 10% based on the total content of the composition. Additives (f) can be, for example, thermal initiators, binders, stabilizers, and mixture thereof.

The choice of additives is governed by the field of use in question and the properties desired for that field. The additives (f) described above are known in the art and are accordingly used in the amounts conventionally used in the art.

For instance, especially in the case of pigmented compositions, the composition may also comprise, as additional additive (f), a thermal initiator, a compound that forms free radicals when heated, e.g. an azo-compound, such as 2,2′-azobis(4-methoxy-2,4-dimethylvaleronitrile), a triazene, diazosulfide, pentazadiene or a peroxy compound, for example a hydroperoxide or peroxycarbonate, e.g. tert-butyl hydroperoxide, as described e.g. in EP 245 639. Binders may also be added to the photocurable composition herein disclosed. The addition of binders is particularly advantageous when the photocurable compounds are liquid or viscous substances. The amount of binder may be, for example, from 5 to 60% by weight, preferably from 10 to 50% by weight, based on the total content of the composition, excluding possible water and solvents. The choice of binder is made in accordance with the field of use and the properties required therefor, such as developability in aqueous and organic solvent systems, adhesion to substrates and sensitivity to oxygen.

Suitable binders are, for example, polymers having a weight average molecular weight (Mw) of approximately from 5,000 Da to 2,000,000 Da, preferably from 10,000 Da to 1,000,000 Da. Illustrative examples are: homo- and copolymers of acrylates and methacrylates, e.g. copolymers of methyl methacrylate/ethyl acrylate/methacrylic acid, poly(methacrylic acid alkyl esters), poly(acrylic acid alkyl esters); cellulose esters and ethers, such as cellulose acetate, cellulose acetate butyrate, methylcellulose, ethylcellulose, polyvinylbutyral, polyvinylformal, cyclised rubber, polyethers such as polyethylene oxide, polypropylene oxide, polytetrahydrofuran, polystyrene, polycarbonates, polyurethanes, chlorinated polyolefins, e.g. polyvinyl chloride, co-polymers of vinyl chloride/vinylidene chloride, co-polymers of vinylidene chloride with acrylonitrile, methyl methacrylate and vinyl acetate, polyvinyl acetate, co-poly (ethylene/vinyl acetate), polymers such as polycaprolactam and poly(hexamethylene adipamide), polyesters such as poly(ethylene glycol terephthalate) and poly(hexamethylene glycol succinate).

Suitable stabilizers are, for example, thermal inhibitors, such as hydroquinone, hydroquinone derivatives, p-methoxyphenol, β-benzol or sterically hindered phenols, e.g. 2,6-di(tert-butyl)-p-cresol, which prevent premature polymerization. In order to increase dark storage stability it is possible to use, for example, copper compounds, such as copper naphthenate, stearate or octoate, phosphorus compounds, for example triphenylphosphine, tributylphosphine, triethyl phosphite, triphenyl phosphite or tribenzyl phosphite, quaternary ammonium compounds, e.g. tetramethylammonium chloride or trimethylbenzylammonium chloride, or hydroxylamine derivatives, e.g. N,N-diethylhydroxylamine. For the purpose of excluding atmospheric oxygen during polymerization it is possible to add paraffin or similar wax-like substances which, being insoluble in the polymer, migrate to the surface at the beginning of the polymerization and form a transparent surface layer which prevents air from entering.

It is also possible to add a light stabilizer, such as UV absorbers, e.g. hydroxyphenylbenzotriazole, hydroxyphenylbenzophenone, oxalic acid amide or hydroxyphenyl-s-triazine type. Such components can be used on their own or in the form of mixtures, with or without the use of sterically hindered amines (HALS).

The photocurable compositions according to the invention may also comprise, as further additives (f), photoreducible dyes, e.g. a xanthene, benzoxanthene, benzothioxanthene, thiazine, pyronin, porphyrin or acridine dye, and/or radiation cleavable trihalomethyl compounds. These compounds are described, for example, in EP445624.

Further customary additives (f) are, depending upon the intended use, optical brighteners, fillers, pigments, both white and colored pigments, colorants, antistatics, wetting agents or flow improvers. Additives conventionally used in the art, e.g. antistatics, flow improvers and adhesion enhancers, can also be used.

In addition to the above components, other components may be present in the composition herein disclosed.

It is also possible for chain-transfer reagents conventionally used in the art to be added to the compositions herein disclosed. Examples are mercaptans, amines and benzothiazole.

The composition herein disclosed may also comprise colorants and/or colored pigments. Depending upon the intended use, both inorganic and organic pigments may be used. Such additives are well known to the person skilled in the art; some examples are carbon black, iron oxides, such as iron oxide yellow, iron oxide red, chromium yellow, chromium green, nickel titanium yellow, ultramarine blue, cobalt blue, bismuth vanadate, cadmium yellow and cadmium red. Examples of organic pigments are mono- or bis-azo pigments, and also metal complexes thereof, phthalocyanine pigments, polycyclic pigments, e.g. perylene, anthraquinone, thioindigo, quinacridone or triphenylmethane pigments, and also diketo-pyrrolo-pyrrole, isoindolinone, e.g. tetrachloroisoindolinone, isoindoline, dioxazine, benzimidazolone and quinophthalone pigments. The pigments may be used in the formulations on their own or in admixture.

Depending upon the intended use, the pigments can be added to the formulations in amounts conventionally used in the art, for example in an amount from 0.1 to 30% by weight or from 10 to 25% by weight, based on the total weight of the composition.

The composition may also comprise, for example, organic colorants of an extremely wide variety of classes. Examples are azo dyes, methine dyes, anthraquinone dyes and metal complex dyes. Usual concentrations are, for example, from 0.1 to 20% wt, especially from 1 to 5% wt, based on the total weight of the composition.

The photocurable compositions herein disclosed may comprise water.

The photocurable compositions herein disclosed are suitable for various purposes, for example as a printing ink, such as screen printing inks, flexographic printing inks, offset printing inks and inkjet printing inks, as clearcoats, as colored coats, for example for wood or metal, as powder coatings, as coating materials inter alia for paper, wood, metal or plastics, as daylight-curable paints for marking structures and roads, for photographic reproduction processes, for holographic recording materials, for image-recording processes or in the production of printing plates that can be developed using organic solvents or using aqueous-alkaline media, for the production of masks for screen printing, as dental filling compounds, as adhesives, as pressure-sensitive adhesives, as laminating resins, as photoresists, e.g. galvanoresists, as etch resists or permanent resists, both liquid and dry films, as photostructurable dielectrics, and as solder masks for electronic circuits, as resists in the production of color filters for any type of display screen or in the creation of structures during the manufacture of plasma displays and electroluminescent displays, in the production of optical switches, optical gratings (interference gratings), in the manufacture of three-dimensional articles by bulk curing (UV curing in transparent moulds) or according to the stereolithography process, as described, for example, in U.S. Pat. No. 4,575,330, in the manufacture of composite materials (e.g. styrene polyesters which may include glass fibers and/or other fibers and other adjuvants) and other methods of printing in three dimensions well-known to one skilled in the art, in the coating or sealing of electronic components or as coatings for optical fibers.

The photocurable compositions herein disclosed are also suitable for the production of optical lenses, e.g. contact lenses or Fresnel lenses, in the manufacture of medical apparatus, aids or implants, in dry film paints.

The photocurable compositions herein disclosed are also suitable for the preparation of gels having thermotropic properties. Such gels are described for example in DE 19700064 and EP 678534.

An article of manufacture, including printed, coated and fabricated assemblies obtained by the process of the invention represents a further subject-matter of the invention.

The compounds and compositions according to the invention may also be used as free-radical photoinitiators or photoinitiating systems for radiation-curable powder coatings in the process of the invention.

By using the process of the invention, the photocurable compositions herein disclosed are suitable, for example, as coating materials for all kinds of substrate, for example wood, textiles, paper, ceramics, glass, plastics, such as polyesters, polyethylene terephthalate, polyolefins and cellulose acetate, especially in the form of films, and also metals, such as Al, Cu, Ni, Fe, Zn, Mg or Co and GaAs, Si or SiO₂, to which a protective layer is to be applied or an image is to be applied e.g. by imagewise exposure.

According to the invention, the photopolymerizing process is carried out by means of at least two different LED light wavelengths, at least one being equal or lower than 300 nm and at least one being higher than 300 nm, provided that the at least two LED light wavelengths are separated by at least 10 nm, preferably at least 20 nm, more preferably at least 30 nm.

Preferably, the photopolymerizing process of the invention is carried out by means of at least two different LED light wavelengths, at least one being from 260 nm to 300 nm and at least one being from higher than 300 nm to 405 nm, provided that the at least two LED light wavelengths are separated by at least 10 nm, preferably at least 20 nm, more preferably at least 30 nm.

Preferably, the at least two LED light wavelengths are separated by 60-110 nm, for example about 70-100, or 80-90.

Preferably, the photopolymerizing process of the invention is carried out by means of at least two different LED light wavelengths, at least one being from 260 nm to 290 nm and at least one being from 365 nm to 405 nm.

Preferred LED light wavelengths are selected from 365, 375, 385, 395, 405, 278 and 280 nm.

No specific LED light wavelength sequence is to be followed, provided at least two different wavelengths are used in the process of the invention. Otherwise said, i.e. the higher wavelength(s) may be used first and the lower wavelength(s) after, or vice versa.

Also, more than two LED light wavelengths may be used, for instance three or four.

Preferably, two LED light wavelengths are used.

Preferably, two LED light wavelengths are used, one being from 260 nm to 290 nm and the other being from 365 nm to 405 nm.

Preferably, two LED light wavelengths are used and are selected from 365, 375, 385, 395, 405, 278 and 280 nm.

Preferably, two LED light wavelengths are used, one LED light wavelength being 278 nm and the other being 365 nm.

As known, LED light wavelengths are emitted by LED lamps.

In the process of the invention, the at least two different LED light wavelengths may be emitted either by at least two separate LED lamps or by a single LED lamp emitting the at least two different LED light wavelengths.

According to the invention the distance between the LED lamps and the substrate to be exposed may vary according to the intended use and the type and strength of the lamps, e.g. from 0.1 cm to 150 cm, preferably from 1 cm to 50 cm.

Said photopolymerizable composition may also be applied over a substrate already comprising a coated or printed layer. Said photopolymerizable composition may, after photopolymerization with said light source, be overprinted or overcoated with one or more compositions suitable for printing or coating.

The article obtained by the photopolymerizable process of the invention, with or without further elaboration of the article by further coating or printing, represents a further subject-matter of this invention.

As it will be shown in the Experimental Section, we surprisingly found that compounds used in the process of the invention have a very high reactivity and low post cure yellowing when cured under a combination of LED lamps compared to two known PIs belonging to the same chemical class.

Indeed, the results showed that not any PI is able to provide high polymerizing reactivity when used according to the process of the invention. This means that the combined use of the two LED lamps provides an unexpected synergistic effect on the reactivity of the specific compounds of formula (I) and (II).

The invention is illustrated in detail below by the following examples, which are illustrative and not limiting.

### EXPERIMENTAL SECTION

### Comparative Tests

The activity of representative photoinitiators (PIs) in the process of the invention was compared with the photoinitiators Omnirad® 1173 (marketed by IGM Resins) and Compound 20 disclosed in U.S. Pat. No. 4,321,118, herein also referred to as COMP-1 and COMP-2, respectively, having the following formulae:

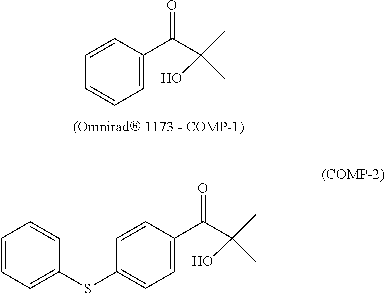 [SMILES: CC(C)(O)C(=O)c1ccccc1 ; CC(C)(O)C(=O)c1ccc(Sc2ccccc2)cc1]

### Example 1

### Tack-Free in Clear Formulation

The photopolymerizable compositions for the test were prepared by dissolving the PIs at the concentration of 6% by weight in a solution of Photomer 3016 (aliphatic urethane acrylate) 70% and Photomer 4061 (TPGDA) 30%.

The PIs were tested with
a UV LED lamp 365 nm 16 W/cm²,
a UV LED lamp 278 nm 4 W/cm², and
a UV LED lamp 365 nm 16 W/cm² in combination with a UV LED lamp 278 nm 4 W/cm².

The photopolymerizable composition is spread with a thickness of 24 g/m² on a BYK coated cardboard.

The results are expressed in meters per minutes as the maximum speed at which the tack-free is reached in Table 1. The higher the value obtained the better the reactivity of the PIs. A value higher than 30 is considered as an acceptable reactivity.

TABLE 1
Tack-free m/min

| | | | LED 365 nm + |
|---|---|---|---|
| PI | LED 365 nm | LED 278 nm | LED 278 nm |
| COMP-1 | <10 | <10 | <10 |
| COMP-2 | <10 | <10 | 15 |
| Omnirad 601 | <10 | 16 | 73 |
| Esacure ONE | <10 | 16 | 36 |
| Omnirad 127 | <10 | 18 | 36 |
| Omnirad 2959 | <10 | 21 | 42 |
| Compound | <10 | 19 | 39 |
| formula (Ia) | | | |

### Example 2

### Yellowing in Clear Formulation

The yellowing of photocurable composition prepared in Example 1 was measured 24 h after curing as absolute value and refer to the ISO E313 with reading setting D65 10°. A value below 16.5 means that a low yellowing performance is achieved.

TABLE 2
Yellowing

| | | | LED 365 nm + |
|---|---|---|---|
| PI | LED 365 nm | LED 278 nm | LED 278 nm |
| COMP-1 | * | * | * |
| COMP-2 | * | * | 20.6 |
| Omnirad 601 | * | 15.6 | 15.6 |
| Esacure ONE | * | 15.5 | 15.8 |
| Omnirad 127 | * | 15.4 | 15.9 |
| Omnirad 2959 | * | 15.7 | 15.7 |
| Compound | * | 15.8 | 16.0 |
| formula (Ia) | | | |

*not measurable

The above results show that the use of a single LED lamp does not provide significant reactivity on all the tested PIs, but, unexpectedly, the combined use of the two LED lamps results in a synergistic effect on the reactivity of compounds of formula (I), while no effect is still obtained on the reactivity of the Comparative PIs, notwithstanding the similar chemical structures.

1. A photopolymerizing process of a photopolymerizable composition comprising a photoinitiator of formula (I) 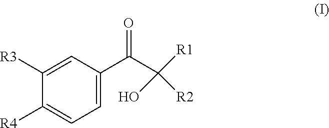
wherein
R1 and R2, each independently, in any occurrence, are C1-C4 alkyl;
and
either
R3 is H;
R4 is selected from C1-C6-alkoxy, hydroxy-C1-C4-alkoxy, linear or branched C1-C12-alkyl, unsubstituted phenoxy, unsubstituted benzyl, unsubstituted phenyl, and group of formula (a) or (b): 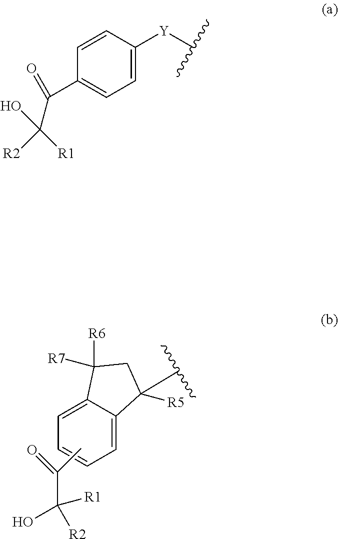
wherein
Y is selected from —O—, —CH2-, —CHOH—, —CH(alk)-, and —C(alk)₂-, wherein alk is a C1-C4 alkyl;
R5, R6 and R7, each independently, are C1-C4-alkyl; and
The wavy line indicates the link to the phenyl group of formula (I);
or
R3 and R4, together with the two carbon atoms to which they are linked, form a group of formula (c): 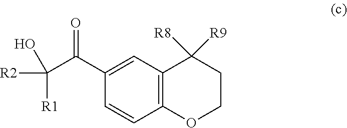
wherein
R8 and R9, each independently, are H or C1-C4 alkyl; and
the stars indicate the positions of R3 and R4 in formula (I);
wherein said photopolymerizing process is carried out by means of at least two different LED light wavelengths, at least one being equal or lower than 300 nm and at least one being higher than 300 nm, provided that the at least two LED light wavelengths are separated by at least 10 nm,
and wherein said photopolymerizable composition does not comprise any liquid crystals.

2. The photopolymerizing process according to claim 1, wherein said photopolymerizable process is carried out by means of at least two different LED light wavelengths, at least one being from 260 nm to 290 nm and at least one being from 365 nm to 405 nm.

3. The photopolymerizing process according to claim 1, wherein R1, R2, R5, R7, R8 and R9 are, each independently, a methyl or ethyl group, more preferably R1, R2, R5, R6, R7, R8 and R9 are all a methyl group.

4. The photopolymerizing process according to claim 1, wherein R4 is hydroxy-C1-C4-alkoxy group.

5. The photopolymerizing process according to claim 1, wherein R4 is hydroxy-ethoxy.

6. The photopolymerizing process according to claim 1, wherein Y is selected from —O— and —CH2-.

7. A photopolymerizable composition comprising;
a) from 50 to 99% by weight, based on the total content of the composition of at least one ethylenically unsaturated compound;
b) from 0.1 to 20% by weight, based on the total content of the composition, of at least one compound of formula (I) as defined in claim 1;
in a photopolymerizing process wherein, said photopolymerizable process is carried out by means of at least two different LED light wavelengths, at least one being equal or lower than 300 nm and at least one being higher than 300 nm, provided that the at least two LED light wavelengths are separated by at least 10 nm, wherein said photopolymerizable composition does not comprise any liquid crystal.

8. The photocurable composition of claim 7, further comprising one or more of the following components:
c) from 0 to 20% by weight, based on the total content of the composition, of one or more accelerator and/or of one or more coinitiator and/or
d) from 0.01 to 15% by weight based on the total content of the composition of one or more sensitizers; and/or
e) from 0.5 to 15% by weight based on the total content of the composition, one or more further photoinitiators.

9. The photocurable composition of claim 8, wherein said accelerator and/or coinitiator is an amine.

10.-14. (canceled)

15. The photopolymerizing process of claim 1, wherein the at least two LED light wavelengths are separated by at least 20 nm.

16. The photopolymerizing process according to claim 1, wherein the at least two LED light wavelengths are separated by at least 30 nm.

17. The photocurable composition of claim 8, wherein said accelerator and/or coinitiator is a tertiary amine.
